(19) United States
(12) Patent Application Publication
(10) Pub. No.: US 2012/0326257 A1
(43) Pub. Date: Dec. 27, 2012

(54) PHOTOELECTRIC CONVERSION LAYER STACK-TYPE SOLID-STATE IMAGING DEVICE AND IMAGING APPARATUS

(75) Inventor: Takuya Takata, Kanagawa (JP)

(73) Assignee: FUJIFILM CORPORATION, Tokyo (JP)

(21) Appl. No.: 13/581,972

(22) PCT Filed: Mar. 15, 2011
(86) PCT No.: PCT/JP2011/056685

§ 371 Date: Aug. 30, 2012

(30) Foreign Application Priority Data
Mar. 19, 2010 (JP) 2010-065203
Nov. 18, 2010 (JP) 2010-258399

(51) Int. Cl. H01L 27/146

(52) U.S. Cl. 257/432; 257/E27.13

(57) ABSTRACT

A photoelectric conversion layer stack-type solid-state imaging device includes a semiconductor substrate, a photoelectric conversion portion, a conductive light shield film, and a dielectric layer. A signal reading portion is formed on a semiconductor substrate. The photoelectric conversion portion is stacked above a light incidence side of the semiconductor substrate and includes a photoelectric conversion layer formed between a first electrode film and a second electrode film which is divided into a plurality of regions corresponding to pixels respectively. The conductive light shield film is stacked above the light incidence side of the photoelectric conversion portion outside an effective pixel region. The dielectric layer is disposed between the conductive light shield and the first electrode film. A given voltage is applied to the first electrode film through a lowpass filter formed by a resistance of wiring to the first electrode film and a capacitor formed between the conductive light shield film and the first electrode film.

### TECHNICAL FIELD

The present invention relates to a solid-state imaging device with a stacked photoelectric conversion layer and an imaging apparatus including the solid-state imaging device.

### BACKGROUND ART

In conventional, commonly used CCD and CMOS image sensors (solid-state imaging devices), a photodetecting region (effective pixel region) consisting of plural pixels (photoelectric conversion portions, photodiodes) that are arranged in two-dimensional array form is formed in a semiconductor substrate surface portion and subject image signals corresponding to a subject optical image formed on the photodetecting region are output from the respective pixels. An optical black (OB) region that is covered with a light shield film is formed around the photodetecting region, and an offset component of each of subject image signals that are output from the photodetecting region is removed using, as a reference signal, a dark signal that is output from the OB region.

Subtracting a noise component (dark current; equal to an output of the OB region) that thermally occurs even without incident light from each subject image signal (each output of the photodetecting region) makes it possible to detect, with high accuracy, faint subject image signals that are output from the photodetecting region and to thereby realize a solid-state imaging device having a large S/N ratio.

In the above-described conventional CCD and CMOS solid-state imaging devices, the photoelectric conversion portions (photodiodes) and signal reading circuits (charge transfer channels and an output amplifier in the case of the CCD type and MOS transistor circuits in the case of the CMOS type) need to be formed in the same semiconductor substrate surface portion. This raises a state that the ratio of the total area of the photoelectric conversion portions to the chip area of the solid-state imaging device cannot be set to 100%. A recent trend of a decreasing aperture ratio due to miniaturization of pixels is a factor of S/N ratio reduction.

In these circumstances, attention has come to be paid to solid-state imaging devices that are configured in such a manner that photoelectric conversion portions are not formed in a semiconductor substrate surface portion and only signal reading circuits are formed in the semiconductor substrate and that a photoelectric conversion film is stacked over the semiconductor substrate.

For example, in the stack-type solid-state imaging devices disclosed in JP-A-6-310699 and JP-A-8-250694, X rays or electron beams are detected through photoelectric conversion by an amorphous silicon layer, for example, stacked over a semiconductor substrate surface. In the photoelectric conversion film stack-type solid-state imaging device disclosed in JP-A-2006-228938, a color image of a subject is taken by means of three photoelectric conversion portions having a red detection photoelectric conversion film, a green detection photoelectric conversion film, and a blue detection photoelectric conversion film, respectively.

In the solid-state imaging devices of JP-A-6-310699 and JP-A-8-250694, dark current is detected by stacking a 2-pin-thick (JP-A-6-310699) light shield layer as the topmost layer of the solid-state imaging device around an effective pixel region (photodetecting region). In the solid-state imaging device of JP-A-2006-228938, incidence of light on signal reading circuits is merely prevented by stacking a light shield film between the semiconductor substrate surface and the photoelectric conversion film (bottommost layer). No consideration is given to the structure of an OB region.

### SUMMARY OF INVENTION

### Technical Problem

The photoelectric conversion film stack-type solid-state imaging device of JP-A-2006-228938 cannot produce subject image signals having large S/N ratios because dark current cannot be detected in a state that no light is incident on the photoelectric conversion film (i.e., the photoelectric conversion film is shielded from light). In contrast, the stack-type solid-state imaging devices of Patent documents 1 and 2 can produce image signals having large S/N ratios because the light shield film covers the peripheral portion of the effective pixel region to form the OB region.

However, in stack-type solid-state imaging devices, a photoelectric conversion layer is sandwiched between pixel electrode films and a counter electrode film and a high voltage such as 5 V or 10 V is applied between the two kinds of electrode films. The high voltage is generated by boosting, by a power circuit, of an operating voltage (e.g., 3.3 V) of signal reading circuits on a semiconductor substrate. However, if noise occurring in the power circuit goes into the counter electrode film and is superimposed on image signals, the image quality is degraded. As a result, a high-quality image cannot be obtained even if it is attempted to attain large S/N ratios by forming an OB region.

An object of the present invention is to provide a photoelectric conversion layer stack-type solid-state imaging device which can produce high-quality image signals stably by reducing the influence of noise caused by a power circuit by forming an OB region, as well as an imaging apparatus incorporating such a photoelectric conversion layer stack-type solid-state imaging device.

### Solution to Problem

[1] According to an aspect of the invention, a photoelectric conversion layer stack-type solid-state imaging device includes a semiconductor substrate, a photoelectric conversion portion, a conductive light shield film, and a dielectric layer. A signal reading portion is formed on a semiconductor substrate. The photoelectric conversion portion is stacked above a light incidence side of the semiconductor substrate and includes a photoelectric conversion layer formed between a first electrode film and a second electrode film which is divided into a plurality of regions corresponding to pixels respectively. The conductive light shield film is stacked above the light incidence side of the photoelectric conversion portion outside an effective pixel region. The dielectric layer is disposed between the conductive light shield and the first electrode film. A given voltage is applied to the first electrode film through a lowpass filter formed by a resistance of wiring to the first electrode film and a capacitor formed between the conductive light shield film and the first electrode film.

[2] The photoelectric conversion layer stack-type solid-state imaging device of paragraph [1], wherein a signal obtained from second electrode films existing in at least part of a region where the light shield film is formed is used as a black level signal.

[3] The photoelectric conversion layer stack-type solid-state imaging device of paragraph [1] or [2], wherein the photoelectric conversion layer includes an organic photoelectric conversion layer.

[4] The photoelectric conversion layer stack-type solid-state imaging device of any one of paragraphs [1] to [3], further comprising:

a light transmission layer that is stacked above the light incidence side of the photoelectric conversion portion and that is made of a material that transmits light at least partially,

wherein the conductive light shield film is formed in the same layer as the light transmission layer.

[5] The photoelectric conversion layer stack-type solid-state imaging device of paragraph [4], wherein the light transmission layer is a color filter layer.

[6] The photoelectric conversion layer stack-type solid-state imaging device of any one of paragraphs [1] to [5], further comprising:

a second light shield film that is stacked above the light incidence side of the photoelectric conversion portion outside the effective pixel region,

wherein the two light shield films shield part of the photoelectric conversion portion from light.

[7] The photoelectric conversion layer stack-type solid-state imaging device of paragraph [6], wherein the second light shield film is made of a conductive material and is electrically connected to the conductive light shield film.

[8] The photoelectric conversion layer stack-type solid-state imaging device of paragraphs [1] to [7], wherein the wiring is formed in a shape of a meandering line.

[9] The photoelectric conversion layer stack-type solid-state imaging device of paragraph [1] to [8], wherein resistivity of the wiring is at least 10⁻⁷ Ω·m.

[10] The photoelectric conversion layer stack-type solid-state imaging device of any one of paragraph [1] to [9], wherein the wiring is made of TiN or ITO.

[11] An imaging apparatus comprising the photoelectric conversion layer stack-type solid-state imaging device according to any one of paragraph [1] to [10].

### Advantageous Effects of Invention

The invention makes it possible to take a high-quality shot image because the light shield film is provided outside the effective pixel region to form an OB region. Furthermore, the lowpass filter can be formed by the simple structure and prevent image quality degradation due to power source noise.

### BRIEF DESCRIPTION OF DRAWINGS

FIG. 1 is a functional block diagram of an imaging apparatus according to an exemplary embodiment of the present invention.

FIG. 2A is a schematic view of the surface of a solid-state imaging device shown in FIG. 1.

FIG. 2B is a schematic view of the surface of a solid-state imaging device according to another exemplary embodiment.

FIGS. 3A and 3B are schematic views of the surfaces of solid-state imaging devices according to two other exemplary embodiments, respectively, which correspond to a solid-state imaging device shown in FIG. 1.

FIG. 4A is a schematic sectional view taken along line IV-IV in FIG. 2A.

FIG. 4B is an enlarged view of an important part of FIG. 4A.

FIG. 5 is a circuit diagram of an example circuit for applying a bias voltage to the solid-state imaging device.

FIG. 6 is a graph showing example counter voltage dependence of the output signal of a case that an organic photoelectric conversion layer is used as a photoelectric conversion layer.

FIG. 7 illustrates a meandering resistance of a lowpass filter which is provided between a power circuit and the solid-state imaging device.

FIG. 8 is a table showing an example method for realizing a resistance of the lowpass filter.

FIG. 9 is a graph showing the example method for realizing the resistance of the lowpass filter.

FIG. 10 is a circuit diagram of the lowpass filter.

FIG. 11 is a graph showing a simulation result of the circuit of FIG. 10.

FIG. 12 is a table showing an example method for realizing a capacitance of the lowpass filter.

FIG. 13 is a simplified version of FIG. 4A.

FIG. 14 is an equivalent circuit diagram of the solid-state imaging device of FIG. 13.

FIG. 15 is a schematic sectional view of a solid-state imaging device according to another exemplary embodiment of the invention.

FIG. 16 is a schematic sectional view of a solid-state imaging device according to still another exemplary embodiment of the invention.

FIG. 17 is a schematic sectional view of a solid-state imaging device according to yet another exemplary embodiment of the invention.

FIG. 18 is a schematic sectional view of a solid-state imaging device according to a further exemplary embodiment of the invention.

### DESCRIPTION OF EMBODIMENTS

Exemplary embodiments of the present invention will be hereinafter described with reference to the drawings.

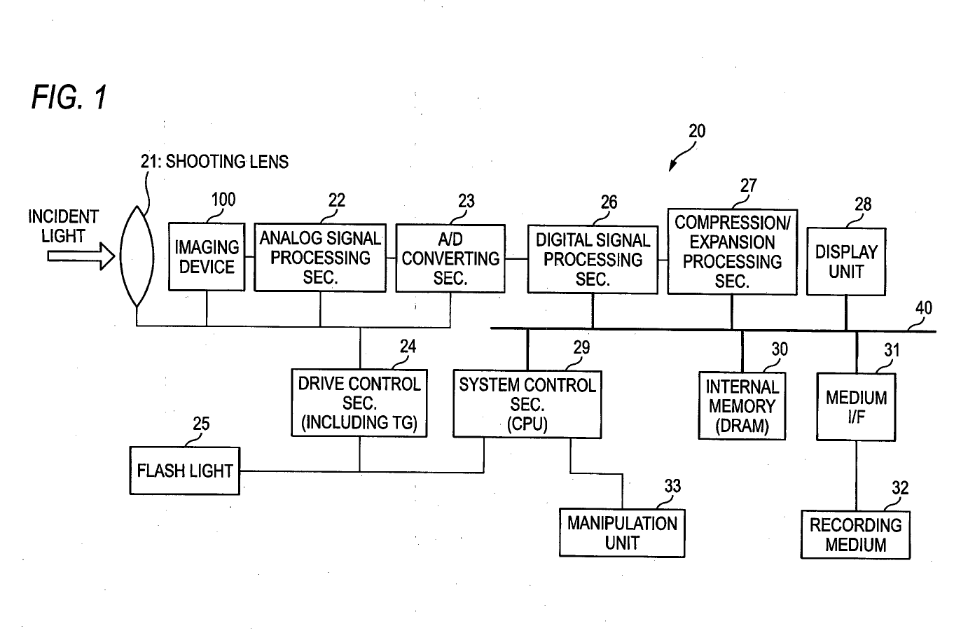

FIG. 1 is a functional block diagram showing the configuration of a digital camera (imaging apparatus) 20 according to an exemplary embodiment of the invention. The digital camera 20 is equipped with a solid-state imaging device 100, a shooting lens 21 which is disposed before the solid-state imaging device 100, an analog signal processing section 22 which performs analog processing such as automatic gain control (AGC) and correlated double sampling on analog image data that is output from the solid-state imaging device 100, an analog-to-digital (A/D) converting section 23 which converts analog image data that is output from the analog signal processing section 22 into digital image data, a drive control section (including a timing generator TG) 24 which drive-controls the shooting lens 21, the A/D-converting section 23, the analog signal processing section 22, and the solid-state imaging device 100 according to an instruction from a system control section (CPU; described later) 29, and a flash light 25 which emits light according to an instruction from the system control section 29. The drive control section 24 also controls of application of a prescribed bias voltage between an upper electrode film 104 and pixel electrode films 113 (both described later).

The digital camera 20 according to the exemplary embodiment is also equipped with a digital signal processing section 26 which captures digital image data that is output from the A/D-converting section 23 and performs interpolation processing, white balance correction, RGB/YC conversion processing, etc. on the digital image data, a compression/expansion processing section 27 which compresses image data into JPEG or like image data or expands JPEG or like image data, a display unit 28 which displays a menu etc. and also displays a through-the-lens image or a shot image, the system control section (CPU) 29 which supervises the entire digital camera 20, an internal memory 30 such as a frame memory, a medium interface (I/F) section 31 which performs interfacing with a recording medium 32 for storing JPEG or like image data, and a bus 40 which interconnects the above blocks. A manipulation unit 33 which receives a user instruction is connected to the system control section 29.

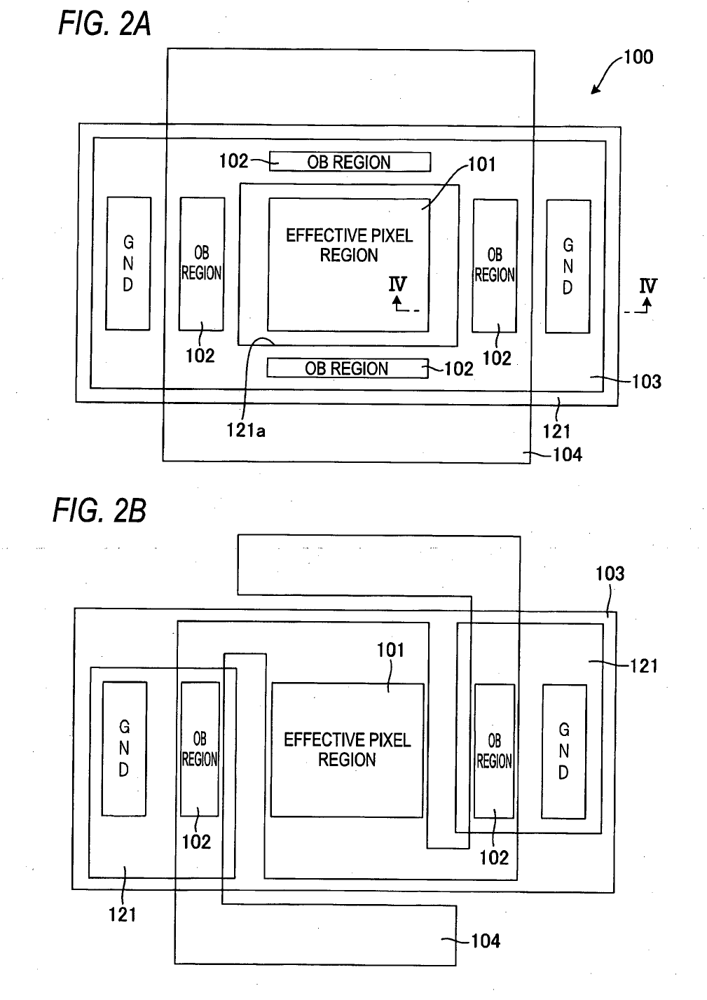

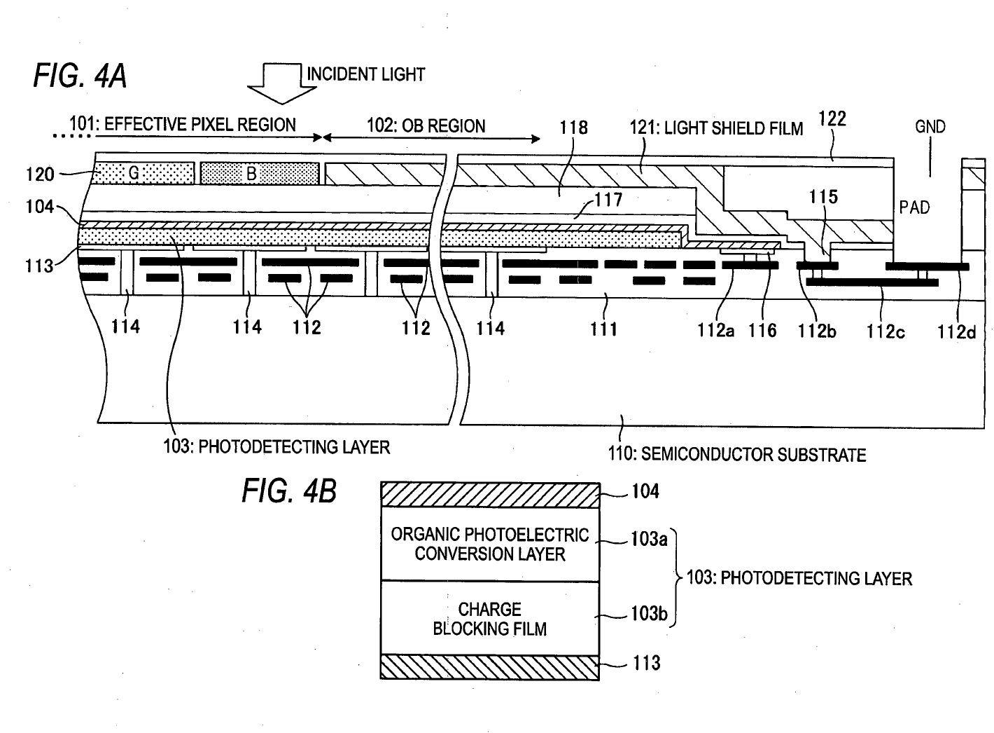

In the exemplary embodiment of FIG. 2A, OB (optical black) regions 102 (their structure will be described later in detail) are formed adjacent to the four sidelines of the photodetecting region 101. A photodetecting layer (described later; see FIG. 4B) occupies a rectangular region 103. An upper electrode film (counter electrode film; described later) occupies a rectangular region 104.

A metal light shield film 121 is formed so as to cover the photodetecting layer 103 and has a light shield film opening 121a in its central portion that includes the effective pixel region 101. Portions GND located outside the right and left OB regions 102 are portions for connecting the light shield film 121 to a ground terminal (described later).

FIG. 2B is a schematic view of the surface of a solid-state imaging device according to another exemplary embodiment. Regions etc. having corresponding ones in FIG. 2A are given the same reference symbols as the latter and will not be described in detail.

In the exemplary embodiment of FIG. 2B, OB regions 102 are formed adjacent to the two (right and left) sidelines of the effective pixel region 101. To take a difference between a dark-time reference signal detected from the OB regions 102 and a pixel signal of each of the pixels in the effective pixel region 101, the OB regions 102 are formed adjacent to the ends of the effective pixel region 101 in the row direction and an OB level is acquired from the pixels in the OB regions 102 in the horizontal blanking period of each horizontal scanning period.

An OB level obtained in each horizontal blanking period is clamped by a correlated double sampling (CDS) circuit of the analog signal processing section 22 shown in FIG. 1 and is used for correction of subject image signals in the effective video period that immediately follows the horizontal blanking period.

In the solid-state imaging device of FIG. 2B, metal light shield films 121 are formed only in regions including the respective OB regions 102. An upper electrode film (first electrode film) 104 which in formed in the effective pixel region 101 extends on the right side and the left side so as to also cover the OB regions 102.

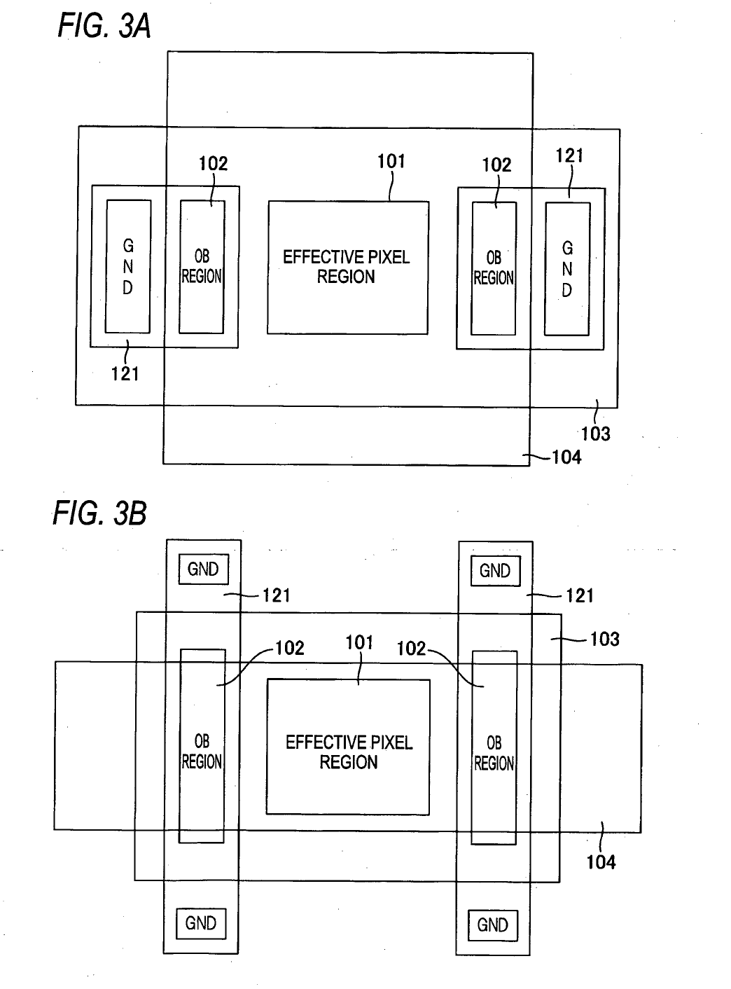

FIGS. 3A and 3B are schematic views of the surfaces of solid-state imaging devices according to two other exemplary embodiments, respectively. The exemplary embodiment of FIG. 3A is different from that of FIG. 2A in that the top and bottom OB regions 102 are omitted and isolated light shield films 121 are formed so as to cover the right and left OB regions 102, respectively. In the exemplary embodiment of FIG. 3B, strip-shaped light shield films 121 are formed so as to cover right and left OB regions 102, respectively.

In each of the solid-state imaging devices of FIGS. 2A and 2B and FIGS. 3A and 3B, the upper electrode film 104 and the light shield film(s) 121 are so wide as to have portions that are opposed to each other with insulating layers (made of a dielectric material; a protective layer 117, a smoothing layer 118, etc. shown in FIG. 4A) interposed in between. As such, the upper electrode film 104 and the light shield film(s) 121 form a capacitor having so large a capacitance as to be used as a lowpass filter.

FIG. 4A is a schematic sectional view of the solid-state imaging device 100 taken along line IV-IV in FIG. 2A. The photoelectric conversion layer stack-type solid-state imaging device 100 is fowled on a semiconductor substrate 110, and MOS circuits (not shown) are formed as signal reading circuits for the respective pixels in a surface portion of the semiconductor substrate 110. Alternatively, CCD signal reading circuits may be employed.

An insulating layer 111 is formed on the surface of the semiconductor substrate 110 and wiring layers 112 are buried in the insulating layer 111. The wiring layers 112 also function as shield plates for preventing leak incident light that is transmitted through the upper layers from entering the signal reading circuits etc.

Plural pixel electrode films (second electrode films) 113 are formed on the surface of the insulating layer 111 so as to be separated from each other so as to correspond to the respective pixels and to be arranged in square lattice form when viewed from above. A vertical wiring 114 extends from each pixel electrode film 113 to the surface of the semiconductor substrate 110, and each vertical wiring 114 is connected to a signal charge storage portion (not shown) formed as a surface portion of the semiconductor substrate 110.

The signal reading circuit for each pixel reads out, as a subject image signal, a signal corresponding to the amount of signal charge stored in the corresponding signal charge storage portion. The pixel electrode films 113 are formed in the effective pixel region 101 and the OB regions 102 shown in FIG. 2A.

A single photodetecting layer 103 (see FIG. 2A) having a photoelectric conversion function is formed on the pixel electrode films 113 (arranged in square lattice form) so as to be common to the pixel electrode films 113, and a single upper electrode film (counter electrode film, common electrode film) 104 is formed on the photodetecting layer 103 (i.e., formed on the light incidence side of the photodetecting layer 103). In the solid-state imaging device 100 according to the exemplary embodiment, the lower electrode films 113 and the upper electrode film 104 and the photodetecting layer 103 which is sandwiched between the films 113 and 104 in the vertical direction constitute a photoelectric conversion portion.

An end portion of the upper electrode film 104 is electrically connected to a connection terminal 116 which is exposed in the surface of the insulating layer 111, and a prescribed voltage (hereinafter referred to as “counter voltage” because the upper electrode film 104 is a counter electrode for the pixel electrode films 113) is applied to the upper electrode film 104 via a wiring layer 112a and a connection pad (not shown).

That is, a prescribed counter voltage (bias voltage) is applied between the upper electrode film 104 and each pixel electrode film 113 by the drive control section 24 (power source) shown in FIG. 1. The metal light shield film 121 is connected to a layer (e.g., ground layer) that is formed over the semiconductor substrate 110 and connected to a voltage source or a potential that is different from the voltage source of the above counter voltage. As a result, the impedance of the portion including the light shield film 121 is made low, whereby the light shield film 121 can be made free of destruction or a charging-dust-collection-induced defect that is caused by charging that occurs in a manufacturing process, for example, without being made complex in structure. Furthermore, the production yield can be increased and image signals can be obtained stably.

A protective layer 117 is laid on the upper electrode film 104 and a smoothing layer 118 is laid on the protective layer 117. Color filters 120 are laid on the smoothing layer 118 in the effective pixel region 101 (see FIG. 2A) so as to correspond to the respective pixel electrode films 113. For example, color filters of the three primary colors red (R), green (G), and blue (B) are Bayer-arranged.

In the solid-state imaging device 100 according to the exemplary embodiment, the light shield film 121 is laid around the effective pixel region 101 in the same layer as the color filters 120. The term “in the same layer” means “in the same plane” and it is preferable that the two layers concerned have the same thickness. The light shield film 121 functions to prevent light coming from above from shining on those portions of the photodetecting layer 103 which are formed in the OB regions 102 so that correct dark-time charge is stored in each signal charge storage portion in the OB regions 102.

The light shield film 121 goes down near its end so that its portion covers a peripheral portion of the protective layer 117. Furthermore, the light shield film 121 is connected to a wiring layer 112b through a hole (short-circuiting portion 115) of the protective layer 117 at a position that is separated outward from the connection terminal 116, and is then connected to a connection pad 112d (ground terminal) via a wiring layer 112c.

That is, a capacitor having the protective layer 117 and the smoothing layer 118 as dielectric layers is formed between the light shield film 121 and the upper electrode film 104. A planarization layer 122 is laid on the color filters 120 and the light shield film 121.

To enable incidence of light on the photodetecting layer 103, the upper electrode film 104 is made of a conductive material that is transparent to incident light. The material of the upper electrode film 104 may be a transparent conducting oxide (TCO) having a high transmittance to visible light and low resistivity.

Although a metal thin film of Au (gold) or the like can be used, its resistance becomes extremely high when its thickness is reduced to attain a transmittance of 90% or more. TCO is thus preferable. Particularly preferable examples TCOs are indium tin oxide (ITO), indium oxide, tin oxide, fluorine-doped tin oxide (FTO), zinc oxide, aluminum-doped zinc oxide (AZO), and titanium oxide. ITO is most preferable in terms of process executability, (low) resistivity, and transparency. Although in the exemplary embodiment the single upper electrode film 104 is formed so as to be common to all the pixels, divisional upper electrode films may be formed so as to correspond to the respective pixels and be connected to a power source.

The lower electrode films (pixel electrode films) 113, which are divisional thin films corresponding to the respective pixels, are made of a transparent or opaque conductive material, examples of which are metals such as Cr, In, Al, Ag, W, TiN (titanium nitride) and TCOs.

The light shield film 121 is made of an opaque metal material, examples of which are copper (Cu), aluminum (Al), titanium nitride (TiN), titanium (Ti), tungsten (W), tungsten nitride (WN), molybdenum (Mo), tantalum (Ta), platinum (Pt), alloys thereof, and silicides thereof (sificides of transition metals). In the case of using a metal material, the light shield film 121 is formed by a known method, that is, a combination of sputtering, evaporation, or the like, photolithography/etching, and a metal mask.

The protective layer 117, the smoothing layer 118, and the planarization layer 122 not only serve for smoothing and planarization in a stacking process but also prevent degradations in the characteristics of an organic photoelectric conversion layer 103a due to a defect (crack, pinhole, or the like) formed therein due to dust etc. occurring in a manufacturing process and aging deteriorations of the photoelectric conversion layer 103a caused by water, oxygen, etc.

The protective layer 117, the smoothing layer 118, and the planarization layer 122 are made of a transparent insulative material, examples of which are silicon oxide, silicon nitride, zirconium oxide, tantalum oxide, titanium oxide, hafnium oxide, magnesium oxide, alumina (Al₂O₃), a polyparaxylene resin, an acrylic resin, and an all-fluorinated transparent resin (CYTOP).

The protective layer 117, the smoothing layer 118, and the planarization layer 122 are formed by a known technique such as chemical vapor deposition (CVD) such as atomic layer deposition (ALD, ALCVD). If necessary, each of the protective layer 117, the smoothing layer 118, and the planarization layer 122 may be a multilayer film of plural insulating films deposited by CVD or atomic layer deposition, or the like. The smoothing layer 118 and the planarization layer 122 are formed by smoothing and planarizing a deposited layer by removing projections by chemical mechanical polishing (CMP).

It is desirable that each of the protective layer 117, the smoothing layer 118, and the planarization layer 122 be as thin as possible while exercise its function. A preferable thickness range is 0.1 to 10 μm.

Next, an example manufacturing method will be described. An insulating layer 111 made of silicon oxide is formed on a semiconductor substrate 110 in which signal charge storage portions and signal reading circuits have been formed by a known process, while wiring layers 112 are buried in the insulating layer 111. Plugs (vertical wirings 114) are formed by forming holes through the insulating layer 111 by photolithography and filling the holes with tungsten.

Then, a TiN film is formed on the insulating layer 111 by sputtering or the like and patterned into lower electrode films (pixel electrode films 113) by photolithography and etching.

Then, a photodetecting layer 103 is formed by depositing a photoelectric conversion material on the lower electrode films 113 by sputtering, evaporation, or the like. A preferable configuration of the photodetecting layer 103 will be described below.

FIG. 4B is a sectional view of the photodetecting layer 103. The photodetecting layer 103 of this exemplary embodiment is composed of a charge blocking film 103b formed on the pixel electrode films 113 and the photoelectric conversion layer 103a made of an organic material which is formed on the charge blocking film 103b.

The charge blocking film 103b has a function of suppressing dark current. The charge blocking film 103b may consist of plural films. In this case, interfaces are formed between the plural charge blocking films, whereby intermediate energy states existing in each film become discontinuous. This makes charge carriers less movable via the intermediate energy states, whereby the dark current is suppressed strongly.

The photoelectric conversion layer 103a includes a p-type organic semiconductor and an n-type organic semiconductor. Forming a donor-acceptor interface by joining the p-type organic semiconductor and the n-type organic semiconductor can increase the exciton dissociation efficiency. Therefore, a photoelectric conversion layer 103a in which the p-type organic semiconductor and the n-type organic semiconductor are joined to each other exhibits high photoelectric conversion efficiency. In particular, a photoelectric conversion layer 103a in which the p-type organic semiconductor and the n-type organic semiconductor are mixed with each other is preferable because an increased junction interface area increases the photoelectric conversion efficiency.

The p-type organic semiconductor (compound) is an acceptor-type organic semiconductor and is an organic compound which tends to accept electrons as typified by a hole-transporting organic compound. More specifically, the p-type organic semiconductor is an organic compound having a lower ionization potential of two organic compounds when they are used being in contact with each other. Therefore, any electron-accepting organic compound can be used as an acceptor-type organic semiconductor.

Usable examples are triarylamine compounds, benzidine compounds, pyrazoline compounds, stytrylamine compounds, hydrazone compound, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, condensed aromatic carbocyclic compounds (naphthalene derivatives, anthracene derivatives, phenanthrene derivatives, tetracene derivatives, pyrene derivatives, perylene derivatives, and fluoranthene derivatives), and metal complexes having a nitrogen-containing heterocyclic compound as a ligand.

As described above, other organic compounds can also be used as an acceptor-type organic semiconductor as long as they have a lower ionization potential than an organic compound used as an n-type (donor-type) compound.

The n-type organic semiconductor (compound) is a donor-type organic semiconductor and is an organic compound which tends to donate electrons as typified by an electron-transporting organic compound. More specifically, the n-type organic semiconductor is an organic compound having higher electron affinity of two organic compounds when they are used being in contact with each other. Therefore, any electron-donating organic compound can be used as a donor-type organic semiconductor.

Usable examples are condensed aromatic carbocyclic compounds (naphthalene derivatives, anthracene derivatives, phenanthrene derivatives, tetracene derivatives, pyrene derivatives, perylene derivatives, and fluoranthene derivatives), 3- to 5-membered heterocyclic compounds containing a nitrogen atom(s), an oxygen atom(s), and/or a sulfur atom(s) (e.g., pyridine, pyrazine, pyrimidine, pydazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotrizole, benzoxazole, benzothiazole, carbazole, purine, triazolopyridazine, triazolopyrimizine, tetrazainedene, oxadiazole, imidazopyridine, pyralizine, pyrrolopyridine, thiadiazolopyridine, dibenzazepine, and tribenzazepine), polyarylene compounds, fluorene compounds, cyclopentadien compounds, silyl compounds, and metal complexes having a nitrogen-containing heterocyclic compound as a ligand.

As described above, other organic compounds can also be used as a donor-type organic semiconductor as long as they have higher electron affinity than an organic compound used as a p-type (acceptor-type) compound.

Although any organic dyes can be used as a p-type or n-type organic semiconductor, preferable examples are a cyanine dye, a styryl dye, a hemicyanine dye, a merocyanine dye, (including a zero-methine merocyanine dye (simple merocyanine dye), a 3-nucleus merocyanine dye, a 4-nucleus merocyanine dye, a rhodacyanine dye, a complex cyanine dye, a complex merocyanine dye, an allopolar dye, an oxonol dye, a hemioxonol dye, a squarium dye, a croconium dye, an azamethine dye, a coumarin dye, an arylidene dye, an anthraquinone dye, a triphenylmethane dye, an azo dye, an azomethine dye, a spiro dye, a metallocene dye, a fluorenone dye, a flugido dye, a perylene dye, a perinone dye, a phenazine dye, a phenothiazine dye, a quinone dye, diphenylmethane dye, a polyene dye, an acridine dye, an acridinone dye, a diphenylamine dye, a quinacridone dye, a quinophtharone dye, a phenoxazine dye, a phthaloperylene dye, a diketopyrrolopyrrole dye, a dioxane dye, a porphyrin dye, a chlorophyll dye, phthalocyanine dye, metal complex dyes, and condensed aromatic carbocyclic dyes (naphthalene derivatives, anthracene derivatives, phenanthrene derivatives, tetracene derivatives, pyrene derivatives, perylene derivatives, and fluoranthene derivatives).

It is particularly preferable to use, as an n-type organic semiconductor, fullerene or a fullerene derivative which is superior in electron transportability. Fullerene includes fullerene C₆₀, fullerene C₇₀, fullerene C₇₆, fullerene C₇₈, fullerene C₈₀, fullerene C₈₂, fullerene C₈₄, fullerene C₉₀, fullerene C₉₆, fullerene C₂₄₀, fullerene C₅₄₀ mixed fullerene, and fullerene nanotube. Usable fullerene derivatives are compounds that are the above various types of fullerene having a substituent group.

Where the photoelectric conversion layer 103a contains fullerene or a fullerene derivative, electrons generated through photoelectric conversion can be transported fast to the pixel electrode films 113 or the counter electrode film 104 via fullerene molecules or fullerene derivative molecules. If an electron path is formed by a succession of fullerene molecules or fullerene derivative molecules, the electron transportability is increased, whereby the solid-state imaging device 100 can exhibit a high response speed. It is therefore preferable that the photoelectric conversion layer 103a contain fullerene or a fullerene derivative at a proportion of 40% or more. However, if fullerene or a fullerene derivative is contained too much, the proportion of p-type organic semiconductor becomes too small and hence the junction interface area becomes too small, as a result of which the exciton dissociation efficiency is lowered.

It is particularly preferable to use, as a p-type organic semiconductor to be used together with fullerene or a fullerene derivative in mixture to form the photoelectric conversion layer 103a, a triarylamine compound as described in Japanese Patent No. 4,213,832 etc., because it allows the solid-state imaging device 100 to exhibit a large S/N ratio. If the photoelectric conversion layer 103a contains fullerene or a fullerene derivative too much, the proportion of the triarylamine compound becomes small, as a result of which the absorptance of incident light is lowered and hence the photoelectric conversion efficiency is lowered. It is therefore preferable that the photoelectric conversion layer 103a contain fullerene or a fullerene derivative at a proportion of 85% or less.

An electron-donating organic material can be used to form the charge blocking film 103b. Example low-molecular-weight materials are aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (α-NPD), oxazole, oxadiazole, triazole, imidazole, imidazolone, stilbene derivatives, pyrazoline derivatives, tetrahydroimidazole, polyarylalkane, butadiene, 4,4′,4″-tris(N-(3-methylphenyl)N-phenylamino)triphenylamine (m-MTDATA), porphine, tetraphenylporphine copper, phthalocyanine, copper phthalocyanine, polyphyline compounds such as titanium phthalocyanine oxide, triazole derivatives, oxadiazole derivatives, imidazole derivatives, polyarylalkane derivatives, pyrazolone derivatives, phenylenediamine derivatives, anylamine derivatives, amino-substituted chalcone derivatives, oxazole derivatives, styrylanthracene derivatives, fluorenone derivatives, hydrazone derivatives, and silazane derivatives. Example high-molecular-weight materials are polymers such as phenylenevinylene, fluorene, carbazole, indole, pyrene, pyrrole, picoline, thiophene, acetylene, and diacetylene, and derivatives thereof. A compound having a sufficient hole-transporting ability can be used even if it is not an electron-donating compound.

An inorganic material can also be used to form the charge blocking film 103b. In general, inorganic materials are higher in permittivity than organic materials. Therefore, where the charge blocking film 103b is made of an inorganic material, a higher voltage develops across the photoelectric conversion layer 103a, whereby the photoelectric conversion efficiency can be increased.

Example materials of the charge blocking film 103b are calcium oxide, chromium oxide, chromium copper oxide, manganese oxide, cobalt oxide, nickel oxide, copper oxide, gallium copper oxide, strontium copper oxide, niobium oxide, molybdenum oxide, indium copper oxide, indium silver oxide, and iridium oxide.

Where the charge blocking film 103b consists of plural films, it is preferable that the film that is adjacent to the photoelectric conversion layer 103a be made of the same material as the p-type organic semiconductor contained in the photoelectric conversion layer 103a. Using, in the charge blocking film 103b, the same p-type organic semiconductor as used in the photoelectric conversion layer 103a makes it possible to suppress the dark current further by preventing formation of intermediate energy states at the interface of the film that is adjacent to the photoelectric conversion layer 103a.

Where the charge blocking film 103b is a single film, it may be made of an inorganic material. Where the charge blocking film 103b consists of plural films, one or more films may be made of an inorganic material.

Returning to the description of the example manufacturing method, an upper electrode film 104 is formed on the photoelectric conversion layer 103a by depositing ITO by sputtering, evaporation, or the like. Then, a protective layer 117 and a smoothing layer 118 are formed on the upper electrode film 104 by physical vapor deposition (e.g., sputtering), chemical vapor deposition (CVD), atomic layer deposition (ALD, ALCVD), or the like.

To prevent substances such as water and oxygen that will deteriorate the photoelectric conversion layer 103a from being mixed into it during formation of the photoelectric conversion layer 103 or the protective layer 117, it is preferable that the photoelectric conversion layer 103a and the protective layer 117 be formed in vacuum or in an inert gas atmosphere consistently.

Then, where a light shield film 121 should be made of a metal material, it is formed around the effective pixel region 101 by a known method, that is, a combination of sputtering, evaporation, or the like, photolithography/etching, and a metal mask.

Then, color filter materials of one color are formed on the portion, in the effective pixel region 101, of the smoothing layer 118 by forming a film of a color filter material and pattering it by photolithography and etching. A color filter layer 120 having a Bayer arrangement, for example, is formed by repeating this process using R, G, and B color filter materials.

Subsequently, a planarization layer 122 is formed on the color filter layer 120 by the same known technique as the protective layer 117 was formed. Microlenses may be formed on the color filter layer 120.

It is preferable that the layers that are stacked on the photoelectric conversion layer 103a be formed at low film formation temperatures. That is, it is preferable that the layers which are stacked on the photoelectric conversion layer 103a be made of materials that enable film formation at low temperatures that are suitable for the heat resistance of the photoelectric conversion layer 103a or be made of materials that are low in heat resistance. It is preferable that the substrate temperature at the time of film formation be lower than or equal to 300° C. It is even preferable that it be lower than or equal to 200° C. And it is most preferable that it be lower than or equal to 150° C.

Likewise, it is preferable that the layer 122 that is laid on the color filter layer 120 be made of a material that enables film formation at a low temperature that is suitable for the heat resistance of the photoelectric conversion layer 103 or be made of a material that is low in heat resistance. It is preferable that the substrate temperature at the time of film formation be lower than or equal to 300° C. It is even preferable that it be lower than or equal to 200° C. And it is most preferable that it be lower than or equal to 150° C.

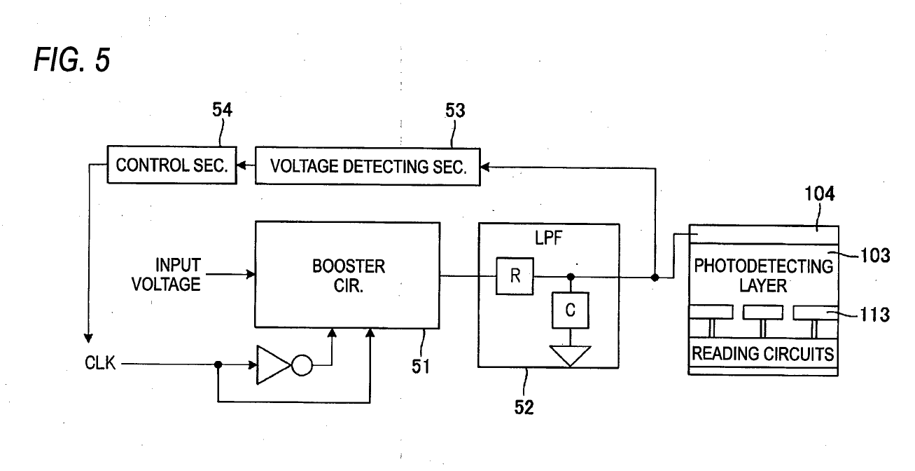

FIG. 5 is a circuit diagram of an example circuit for applying a prescribed counter voltage to the upper electrode film 104 of the solid-state imaging device 100. Usually, MOS transistor circuits (signal reading circuits) formed on a semiconductor substrate operate on a low voltage of 3.3 V, for example.

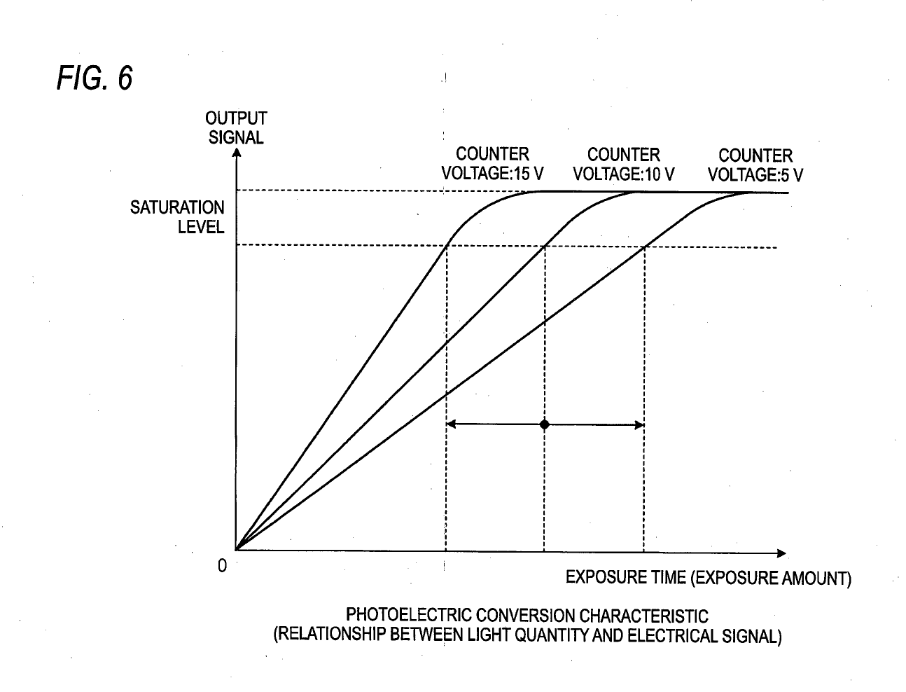

FIG. 6 is a graph showing example counter voltage dependence of the output signal of a case that an organic photoelectric conversion layer is used as a photoelectric conversion layer. Where an organic photoelectric conversion layer is used, the output signal for the same exposure amount increases as the counter voltage is increased. As a result, high-sensitivity shooting of a scene with small light quantities is enabled by controlling the counter voltage to a high voltage. That is, to drive the organic photoelectric conversion layer 103a stably, a technique for applying a prescribed voltage to the upper electrode film 104 stably is very important. However, this counter voltage is higher than the above-mentioned voltage 3.3 V.

Therefore, in the example of FIG. 5, the above-mentioned voltage 3.3 V is employed as an input voltage and subjected to boosting by a booster circuit (power circuit) 51. A resulting voltage is applied to the upper electrode film 104. However, as mentioned above, power source noise may be introduced into the upper electrode film 104. In view of this, in the solid-state imaging device 100 according to the exemplary embodiment, as a noise reducing measure, a lowpass filter 52 is provided between the booster circuit 51 and the upper electrode film 104.

An output voltage of the lowpass filter 52 is detected by a voltage detecting section 53 and the voltage boosting ratio of the booster circuit 51 is controlled using the detected voltage. A prescribed counter voltage is thus obtained. Examples of the booster circuit 51 are a switching regulator circuit and a charge pump circuit. Although a charge pump circuit is inferior to a switching regulator circuit in that the efficiency is low and the output current is small, the former is suitable for a solid-state imaging device because it produces only small noise and does not require inductance.

The lowpass filter 52 requires resistance R and capacitance C. Separately providing capacitance in the circuit causes area increase. However, in the solid-state imaging device 100 according to the exemplary embodiment, this can be avoided (i.e., miniaturization can be attained) because the capacitance formed between the light shield film 121 and the upper electrode film 104 is used.

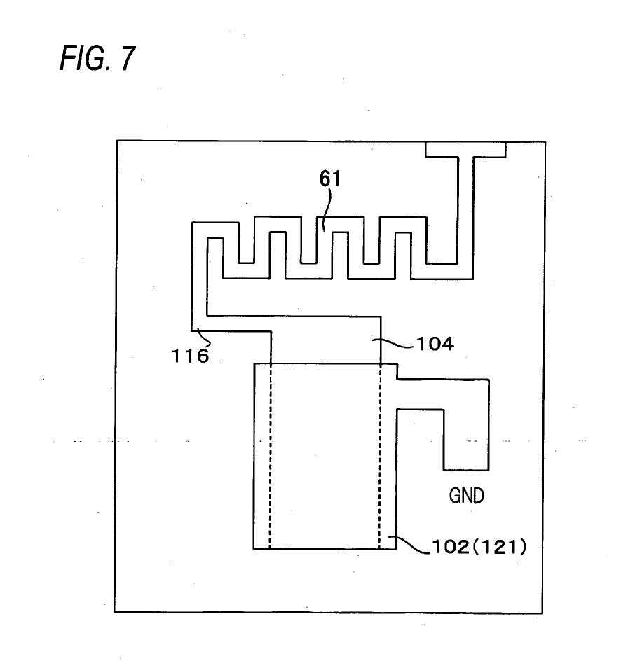

For example, as shown in FIG. 7, the resistance R can be adjusted, while space saving is attained, by forming a meandering wiring 61 which is connected to the connection terminal 116 (connected to the upper electrode film 104 (see FIG. 4A)) and extends in a free metal top region on the surface of the solid-state imaging device 100. FIG. 7 is a schematic drawing how the meandering wiring 61 extends which is connected to the upper electrode film 104 (connection terminal 116) in the OB region 102.

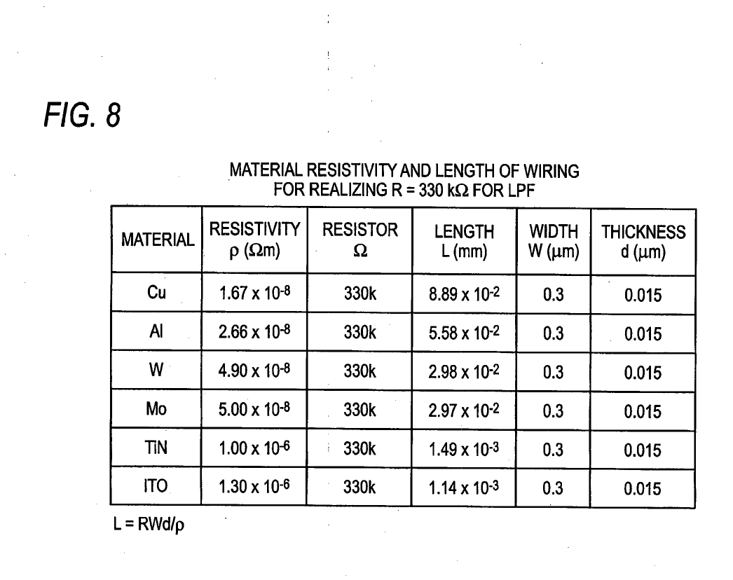

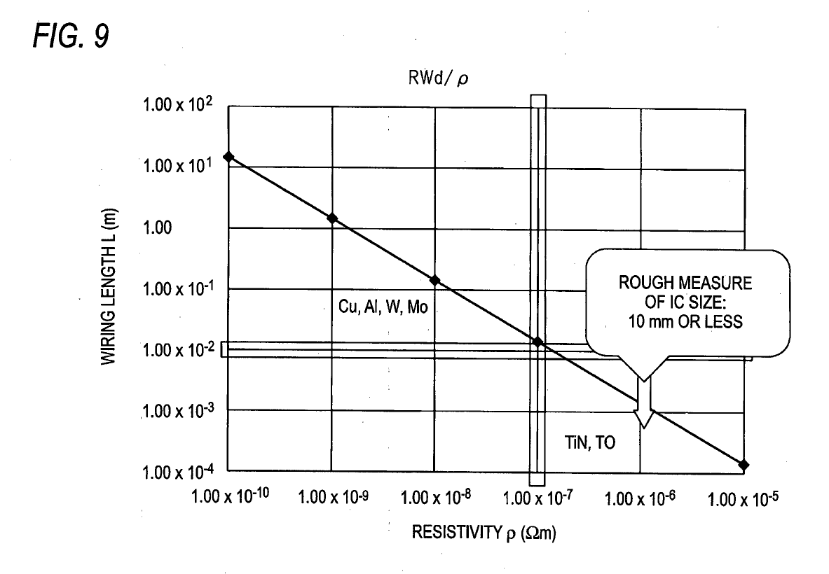

It is preferable that the wiring material be ITO (indium tin oxide) or TiN (titanium nitride) instead of ordinarily used gold (Au), aluminum (Al), or copper (Cu). The wiring is used as a resistance and its length is made so short as to be implementable by utilizing high resistivity of TiN, for example. FIGS. 8 and 9 are a table and a graph showing example combination of wiring material resistivity and a wiring length for realizing a resistance 330 k Ω.

Whereas the resistivity of ordinary wiring materials is on the order of 10⁻⁸ Ω·m, that of TiN is as high as 10⁻⁶ Ω·m or more. TiN is thus suitable to attain a high resistance. Although the wiring material is not limited to TiN, it is preferable that the resistivity be at least 10⁻⁷ Ω·m.

As for the parallel-plate capacitor C which is formed by the upper electrode film 104 and the light shield film 121, a capacitance of several tens of picofarads which is necessary for the lowpass filter 52 can be realized by adjusting the thicknesses of the protective layer 117 etc. formed between the upper electrode film 104 and the light shield film 121 and the relative permittivity values of their materials.

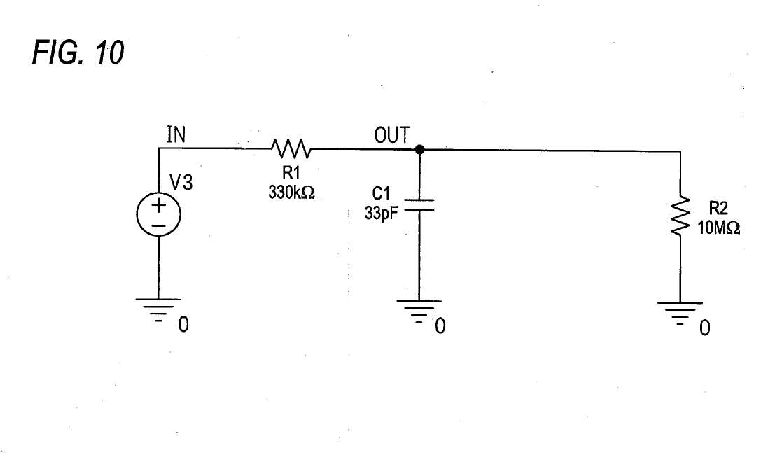

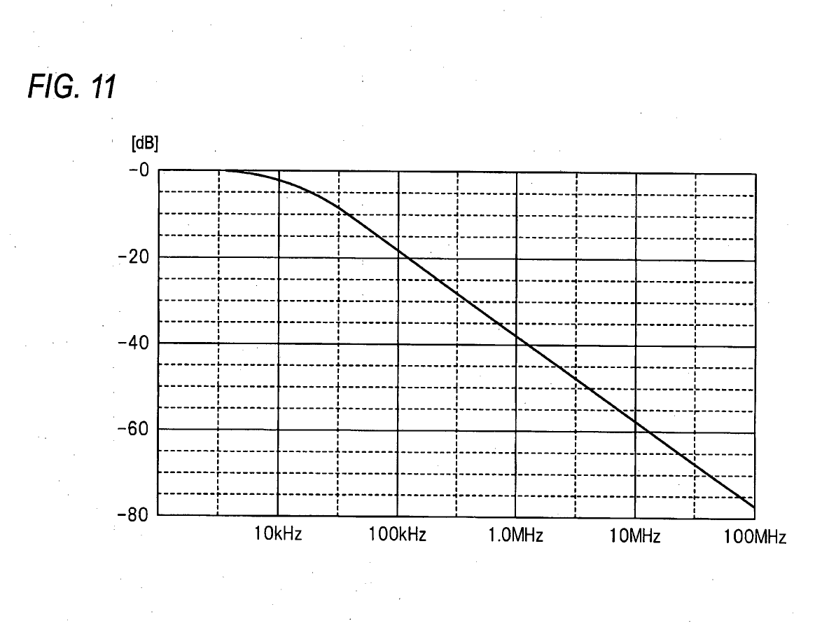

FIG. 10 is a circuit diagram of the lowpass filter 52, and FIG. 11 is a graph showing a simulation result of the circuit of FIG. 10. Output noise of the booster circuit (charge pump circuit) 51 can be shut off by setting the cutoff frequency of the lowpass filter 52 higher than the input clock frequency of the charge pump circuit 51.

For example, where the photodetecting layer 103 operates under conditions of 10 V and 2 μA, the charge pump booster circuit (power circuit) 51 which has an operating frequency 200 kHz and a current consumption 2 μA generates noise of several tens of millivolts (peak-to-peak) due to the operating frequency 200 kHz. With an assumption that a cutoff frequency of the lowpass filter 52 suppressing noise to several millivolts (peak-to-peak) is 15 kHz, a capacitance 33 pF is obtained for a resistance 330 kΩ.

Where the wiring material is TiN, an wiring length is calculated as about 1.5 mm using its resistivity and a voltage drop is about 0.66 V. In the case of VGA (640×480 pixels) with a pixel size of 3 μm×3 μm, the size of the solid-state imaging device 100 is 1.92 mm×1.44 mm. It is therefore seen that the above wiring length is appropriate. If the wiring length is longer than a photodetecting surface size of VGA or the like by a certain degree, such an wiring length can be realized by forming a bent or meandering wiring.

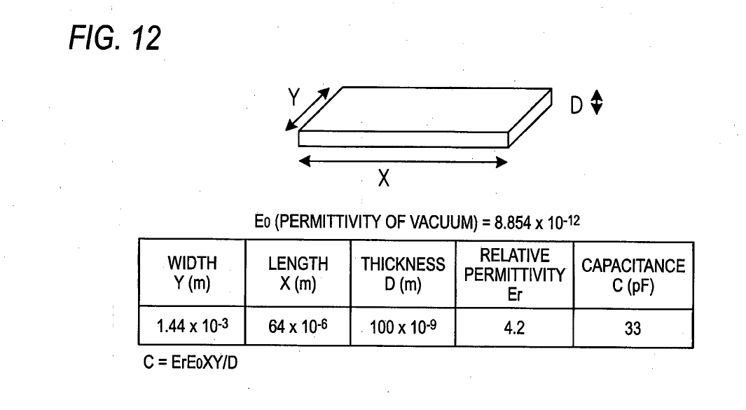

A necessary capacitance 33 pF can be obtained by setting the size of the light shield film 121, the thickness of the protective layer 117 etc., and the relative permittivity at 1.44 mm×0.064 mm, 100 nm, and 4.2, respectively, as shown in FIG. 12.

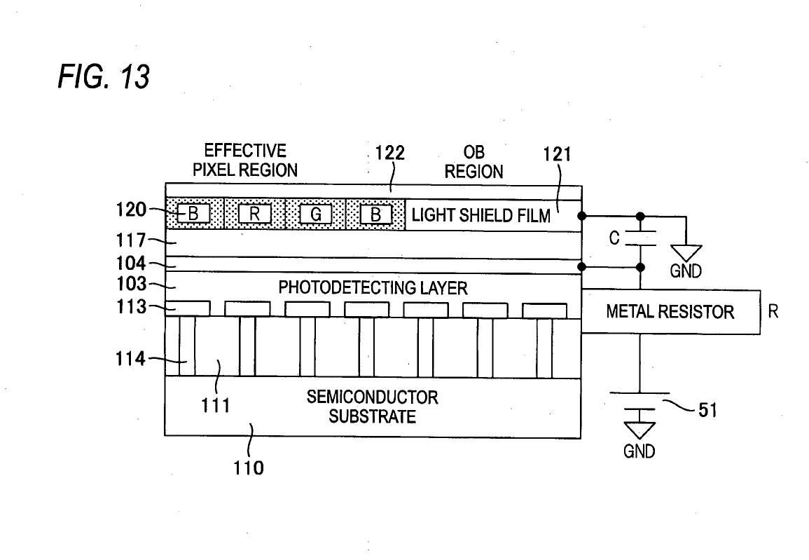

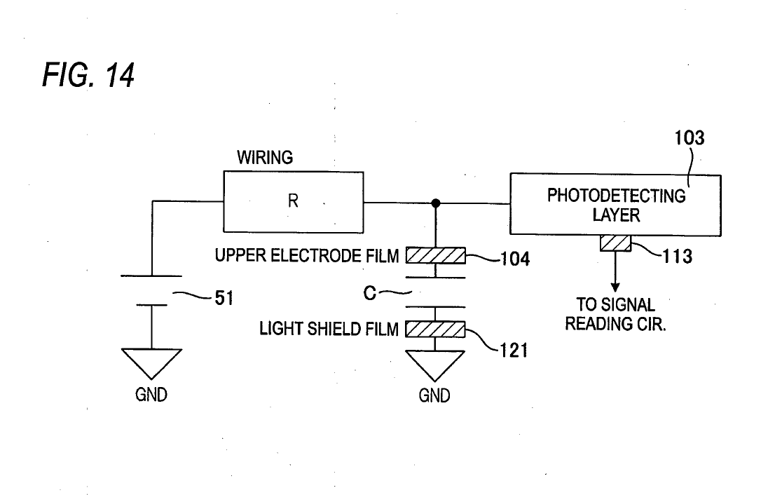

FIG. 13 is a simplified version of the schematic sectional view of FIG. 4A which shows the solid-state imaging device 100 having the light shield film 121. FIG. 14 is an equivalent circuit diagram of the solid-state imaging device 100 of FIG. 13. As shown in FIG. 13, in the solid-state imaging device 100 according to the exemplary embodiment, the light shield film 121 is formed over the upper electrode film 104 in the same layer as the color filter layer 120 with the protective layer 117 (which includes the smoothing layer 118 in FIG. 4) interposed in between. Therefore, the thickness of the solid-state imaging device 100 can be reduced, the entire surface of the solid-state imaging device 100 can be made flat, and color contamination between the effective pixels for image output can be prevented. Furthermore, since the topmost surface of the solid-state imaging device 100 has no step, oblique incidence of light on the OB regions 102 due to such a step can be prevented. The accuracy of a dark-time reference signal can thus be increased.

In the solid-state imaging device 100 according to the exemplary embodiment, the light shield film 121 and the upper electrode film 104 form a parallel-plate capacitor (this capacitor is shown in FIG. 13 as an equivalent capacitor C, that is, the capacitor C is not an external one; this also applies to the following description). Since this capacitor is used as the capacitor C of the lowpass filter 52, an imaging device module incorporating the photoelectric conversion layer stack-type solid-state imaging device 100 can be miniaturized and image signals having large S/N ratios can be obtained.

In the solid-state imaging device 100 according to the exemplary embodiment, a counter voltage is applied to the upper electrode film 104 via the resistance R which has been described above with reference to FIG. 7. And the capacitor C formed between the upper electrode film 104 and the light shield film 121 and the resistance R constitute the lowpass filter 52. As a result, noise generated by the power circuit 51 is prevent from traveling to the upper electrode film 104, whereby image signals having large S/N ratios can be obtained stably.

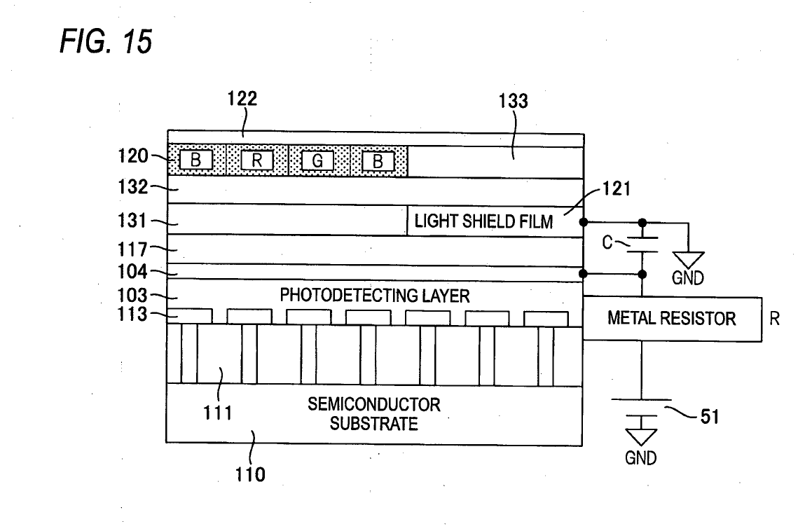

FIGS. 15-18 are schematic sectional views of solid-state imaging devices according to other exemplary embodiments of the invention. It may be necessary to change the structure involving the light shield film 121 (i.e., the structure of FIG. 13 cannot be employed) depending on the stacking conditions such as temperatures, pressures, chemical reactions, etc. that are employed in stacking the photodetecting layer 103, the electrode films 104 and 113, the insulating layers, the color filter layer 120, etc. Even in such a case, the upper electrode film 104 and the light shield film 121 are opposed to each other with the protective layer 117 etc. interposed in between to form a capacitor.

In the exemplary embodiment of FIG. 15, a light shield film 121 is laid on the protective layer 117 which is laid on the upper electrode film 104. The light shield film 121 is formed outside the effective pixel region 101 in the same layer as a second protective layer 131 which is fowled on the protective layer 117. A smoothing layer 132 is laid on the protective layer 131 and the light shield film 121. And the color filter layer 120 and the planarization layer 122 are formed on the smoothing layer 132. In this exemplary embodiment, the color filter layer 120 is formed only in the effective pixel region 101 and an insulating layer 133 is formed around it.

Although in this exemplary embodiment the distance between the photodetecting layer 103 and the color filter layer 120 is longer than in the exemplary embodiment of FIG. 13, it raises no problems because the protective layer 131 and the smoothing layer 132 can be thin.

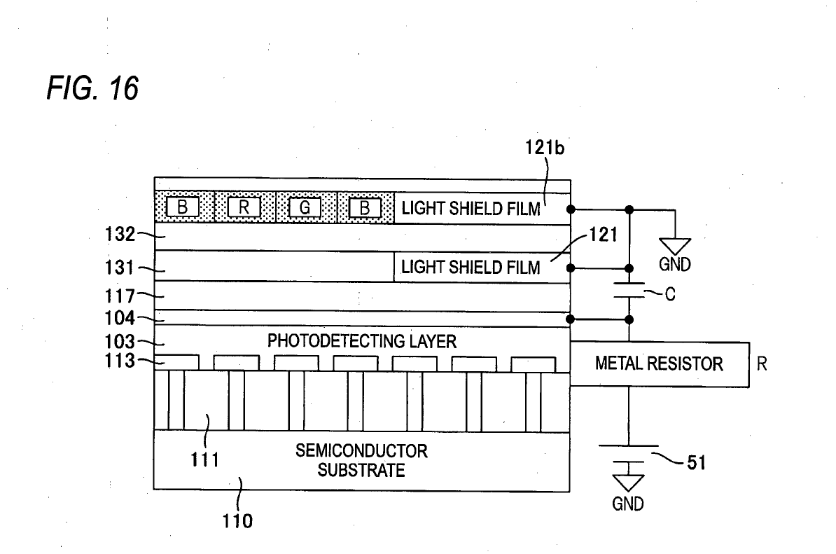

The exemplary embodiment of FIG. 16 is different from that of FIG. 15 in that a second light shield film 121b is provided in place of the insulating layer 133 and the two light shield films 121 and 121b are connected to each other. This exemplary embodiment is superior in light shield performance because of the presence of the two light shield films 121 and 121b. The total area of the light shield films 121 and 121b is larger than in the exemplary embodiment of FIG. 15, the impedance of the portion including the light shield films 121a and 121b is decreased accordingly. This enhances the advantage that light shield films that are free of destruction or a charging-dust-collection-induced defect caused by charging that occurs in a manufacturing process, for example, can be formed and the production yield can be increased.

To short-circuit the two light shield films 121 and 121b, openings are formed through the in-between insulating layers etc. (protective layer and smoothing layers) at the position of the short-circuiting portion 115 (see FIG. 4A) by etching and the upper light shield film 121b is laid thereon. If the light shield film 121b which is more distant from the upper electrode film 104 than the light shield film 121 is made of resin rather than metal, it goes without saying that the resin light shield film 121b need not be short-circuited with the other light shield film 121.

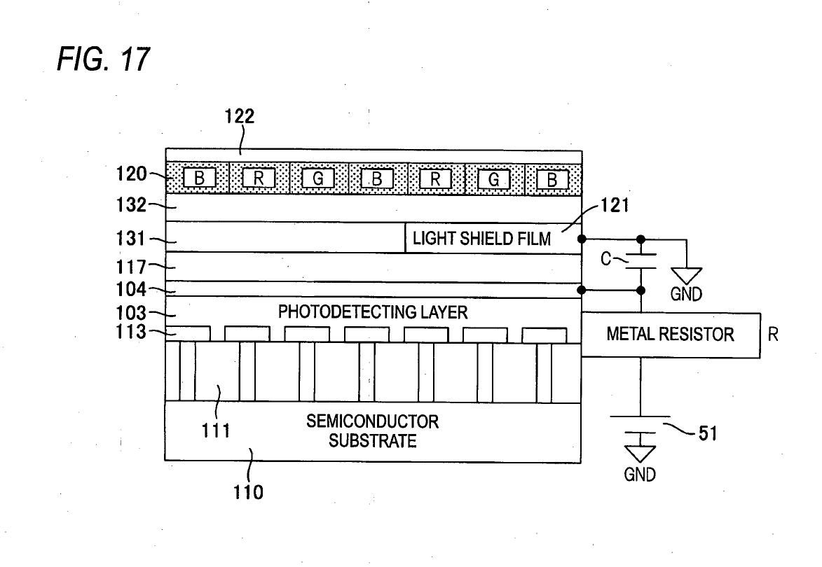

The exemplary embodiment of FIG. 17 is different from that of FIG. 15 in that the color filter layer 120 extends so as to occupy the area of the insulating layer 133. The number of manufacturing steps can be decreased because the color filter layer 120 is formed so as to extend to occupy the area of the insulating layer 133 instead of forming the insulating layer 133 by a separate manufacturing step.

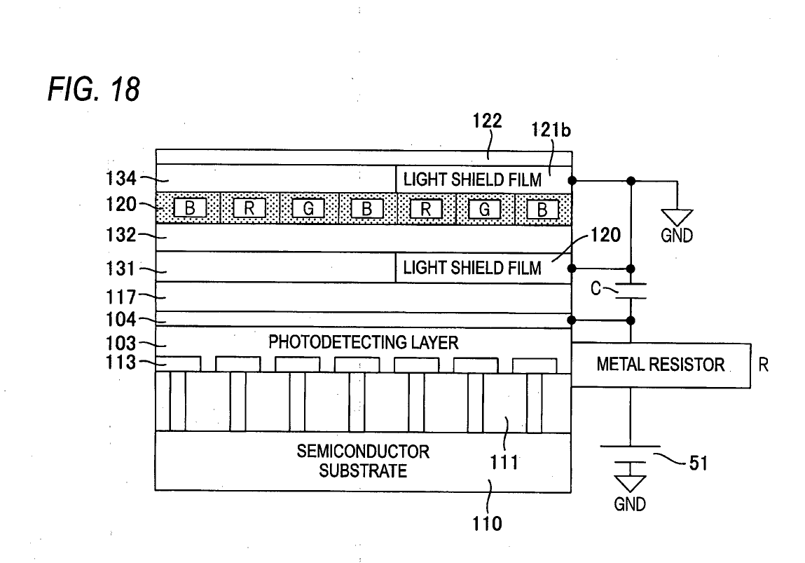

The exemplary embodiment of FIG. 18 is different from that of FIG. 17 in that a second light shield film 121b is formed on the part, outside the effective pixel region 101, of the color filter layer 120. The light shield performance is enhanced because of the two light shield films 121a and 121b. A transparent insulating layer 134 is formed in the effective pixel region 101 in the same layer as the light shield film 121b, and the planarization layer 122 is formed as a topmost layer.

Also in this exemplary embodiment, both of the light shield films 121 and 121b are electrically connected to each other by the short-circuiting portion 115. The impedance of the portion including the light shield films 121 and 121b is decreased and the light shield performance is enhanced.

In the above-described exemplary embodiments, as shown in, for example, FIGS. 3A and 3B, and FIG. 4A, only parts of the regions in which the light shield films 121 are formed, that are located outside the effective pixel region 101, and that are provided with the pixel electrode films 113 are used as the OB regions 102. Alternatively, the entire regions where the light shield films 121 are formed may be used as OB regions.

As described above, a photoelectric conversion layer stack-type solid-state imaging device according to the exemplary embodiments comprises a semiconductor substrate in which signal reading means are formed in a surface portion thereof; a photoelectric conversion portion which is laid on the light incidence side of the semiconductor substrate and is configured in such a manner that a photoelectric conversion layer is formed between a first electrode film and divisional second electrode films corresponding to respective pixels; and a conductive light shield film which is laid on the light incidence side of the photoelectric conversion portion outside an effective pixel region in such a manner that a dielectric layer is interposed between the light shield film and the first electrode film, wherein the first electrode film is supplied with a prescribed voltage via a lowpass filter which is formed by a resistance which is an wiring connected to the first electrode film and a capacitor formed between the light shield film and the first electrode film.

The photoelectric conversion layer stack-type solid-state imaging device may be such that a signal obtained from second electrode films existing in at least part of a region where the light shield film is formed is used as a black level signal.

The photoelectric conversion layer stack-type solid-state imaging device may be such that the photoelectric conversion layer comprises an organic photoelectric conversion layer.

The photoelectric conversion layer stack-type solid-state imaging device may be such that it further comprises a light transmission layer laid on the light incidence side of the photoelectric conversion portion and made of a material that transmits light at least partially, and that the light shield film is formed in the same layer as the light transmission layer.

The photoelectric conversion layer stack-type solid-state imaging device may be such that the light transmission layer is a color filter layer.

The photoelectric conversion layer stack-type solid-state imaging device may be such that it further comprises a second light shield film which is laid on the light incidence side of the photoelectric conversion portion outside the effective pixel region, and that the two light shield films shield part of the photoelectric conversion portion from light.

The photoelectric conversion layer stack-type solid-state imaging device may be such that the second light shield film is made of a conductive material and is electrically connected to the light shield film.

The photoelectric conversion layer stack-type solid-state imaging device may be such that the wiring is a meandering line.

The photoelectric conversion layer stack-type solid-state imaging device may be such that resistivity of the wiring is at least 10⁻⁷ Ω·m.

The photoelectric conversion layer stack-type solid-state imaging device may be such that the wiring is made of TiN or ITO.

An imaging apparatus according to the exemplary embodiments comprises any of the above the photoelectric conversion layer stack-type solid-state imaging devices.

As such, the exemplary embodiments prevent traveling, to the first electrode film, of noise generated by a power source for applying a prescribed voltage to the first electrode film and thereby make it possible to take a high-quality image.

This present application is based on Japanese Patent Application Nos. 2010-065203, filed on Mar. 19, 2010, and 2010-258399, filed on Nov. 18, 2010, the entire contents of which are incorporated hereby by reference.

### INDUSTRIAL APPLICABILITY

Being manufactured at a high yield and a low cost and allowing the user to take high-quality subject images, the photoelectric conversion layer stack-type solid-state imaging device according to the invention can usefully be incorporated in digital still cameras, digital video cameras, cell phones with a camera, electronic apparatus with a camera, monitoring cameras, endoscopes, vehicular cameras, etc.
21: Shooting lens
26: Digital signal processing section
29: System control section
100: Photoelectric conversion layer stack-type solid-state imaging device
101: Effective pixel region
102: OB (optical black) region
103: Photodetecting layer
103a: Photoelectric conversion layer
103b: Charge blocking film
104: Upper electrode film (common electrode film, counter electrode film, first electrode film)
110: Semiconductor substrate
111, 133, 134: Insulating layer
112: Wiring layer
113: Lower electrode film (pixel electrode film, second electrode film)
114: Vertical wiring (plug)
117: Protective layer (dielectric layer)
118: Smoothing layer (dielectric layer)
120: Color filter layer
121, 121b: Light shield film
121a: Opening of light shield film
122: Planarization layer

1. A photoelectric conversion layer stack-type solid-state imaging device comprising:
a semiconductor substrate on which a signal reading portion are formed;
a photoelectric conversion portion that is stacked above a light incidence side of the semiconductor substrate and includes a photoelectric conversion layer formed between a first electrode film and a second electrode film which is divided into a plurality of regions corresponding to pixels respectively; and
a conductive light shield film that is stacked above the light incidence side of the photoelectric conversion portion outside an effective pixel region;
a dielectric layer that is disposed between the conductive light shield and the first electrode film,
wherein a given voltage is applied to the first electrode film through a lowpass filter formed by a resistance of wiring to the first electrode film and a capacitor formed between the conductive light shield film and the first electrode film.

2. The photoelectric conversion layer stack-type solid-state imaging device according to claim 1, wherein a signal obtained from second electrode films existing in at least part of a region where the light shield film is formed is used as a black level signal.

3. The photoelectric conversion layer stack-type solid-state imaging device according to claim 1, wherein the photoelectric conversion layer includes an organic photoelectric conversion layer.

4. The photoelectric conversion layer stack-type solid-state imaging device according to claim 1, further comprising:
a light transmission layer that is stacked above the light incidence side of the photoelectric conversion portion and that is made of a material that transmits light at least partially,
wherein the conductive light shield film is formed in the same layer as the light transmission layer.

5. The photoelectric conversion layer stack-type solid-state imaging device according to claim 4, wherein the light transmission layer is a color filter layer.

6. The photoelectric conversion layer stack-type solid-state imaging device according to claim 1, further comprising:
a second light shield film that is stacked above the light incidence side of the photoelectric conversion portion outside the effective pixel region,
wherein the two light shield films shield part of the photoelectric conversion portion from light.

7. The photoelectric conversion layer stack-type solid-state imaging device according to claim 6, wherein the second light shield film is made of a conductive material and is electrically connected to the conductive light shield film.

8. The photoelectric conversion layer stack-type solid-state imaging device according to claim 1, wherein the wiring is formed in a shape of a meandering line.

9. The photoelectric conversion layer stack-type solid-state imaging device according to claim 1, wherein resistivity of the wiring is at least 10⁻⁷ Ω·m.

10. The photoelectric conversion layer stack-type solid-state imaging device according to claim 1, wherein the wiring is made of TiN or ITO.

11. An imaging apparatus comprising the photoelectric conversion layer stack-type solid-state imaging device according to claim 1.

12. The photoelectric conversion layer stack-type solid-state imaging device according to claim 2, wherein the photoelectric conversion layer includes an organic photoelectric conversion layer.

13. The photoelectric conversion layer stack-type solid-state imaging device according to claim 2, further comprising:
a light transmission layer that is stacked above the light incidence side of the photoelectric conversion portion and that is made of a material that transmits light at least partially,
wherein the conductive light shield film is formed in the same layer as the light transmission layer.

14. The photoelectric conversion layer stack-type solid-state imaging device according to claim 2, further comprising:
a second light shield film that is stacked above the light incidence side of the photoelectric conversion portion outside the effective pixel region,
wherein the two light shield films shield part of the photoelectric conversion portion from light.

15. The photoelectric conversion layer stack-type solid-state imaging device according to claim 2, wherein the wiring is formed in a shape of a meandering line.

16. The photoelectric conversion layer stack-type solid-state imaging device according to claim 2, wherein resistivity of the wiring is at least 10⁻⁷ Ω·m.

17. The photoelectric conversion layer stack-type solid-state imaging device according to claim 2, wherein the wiring is made of TiN or ITO.
